(19) United States
(12) Patent Application Publication
(10) Pub. No.: US 2006/0012056 A1
(43) Pub. Date: Jan. 19, 2006

(54) Semiconductor chip resin encapsulation method

(75) Inventors: Shinji Ueno, Tokyo (JP); Akihito Kawai, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/178,278

(22) Filed: Jul. 12, 2005

(30) Foreign Application Priority Data
Jul. 13, 2004 (JP) 2004-205922

(51) Int. Cl. H01L 23/28

(52) U.S. Cl. 257/787

(57) ABSTRACT

A semiconductor chip resin encapsulation method, including a resin filling and curing step of encapsulating a plurality of semiconductor chips, which have been bonded onto a substrate, in a molten resin, and curing the molten resin. The semiconductor chip resin encapsulation method further includes a grinding step of grinding an upper surface of the cured resin to decrease the thickness of the encapsulating resin to a predetermined value.

### FIELD OF THE INVENTION

This invention relates to a semiconductor chip resin encapsulation method for encapsulating a plurality of semiconductor chips, which have been bonded onto a substrate, in a resin.

### DESCRIPTION OF THE PRIOR ART

In recent times, a semiconductor device of a type called CSP (chip size package) has found wide use, as disclosed in Japanese Patent Application Laid-Open No. 2000-12745. To produce CSP, a plurality of semiconductor chips are bonded onto a substrate, and these plural semiconductor chips are encapsulated in a resin. The so formed article is called a CSP substrate. Then, the CSP substrate is divided at sites between the adjacent semiconductor chips. In this manner, a plurality of CSPs are produced. In encapsulating the plurality of semiconductor chips bonded onto the substrate in the resin, it is common practice to cover the plurality of semiconductor chips on the substrate with a box-shaped mold having an open lower surface, fill a molten resin into the space within the mold, and remove the mold after the filled resin is cured.

The conventional method of encapsulating the semiconductor chips in resin poses the following problems to be solved: CSP, which is a final product, is desired to be as small as possible and, thus, the thickness of the encapsulating resin is also desired to be as small as possible. Generally, therefore, the dimension of the clearance between the uppermost site of the semiconductor chip (if the semiconductor chip is wire-bonded on the substrate, for example, the uppermost site of the bonding wire) and the inner surface of the upper wall of the mold covering the semiconductor chip is set at about 75 μm. As the encapsulating resin, there is used a suitable resin, such as a phenolic resin or an epoxy resin, incorporating a filler composed of suitable particles, such as silica particles, having a particle size of the order of several tens of micrometers. Particularly when the resin incorporating the filler is used, the flow characteristics of the molten resin are not necessarily satisfactory owing to the presence of the filler. Therefore, it is not easy to sufficiently fill the space within the mold with the resin. As a result, voids tend to be formed in the encapsulating resin, or a part of the bonding wire tends to be exposed to the outside, without being encapsulated in the resin.

### SUMMARY OF THE INVENTION

It is a principal object of the present invention, therefore, to provide a novel and improved semiconductor chip resin encapsulation method which can minimize the thickness of the encapsulating resin, without causing a drawback such that voids are formed in the encapsulating resin, or that a part of the bonding wire is not encapsulated in the resin, but is exposed to the outside.

The inventors diligently conducted studies, and have found that the above principal object can be attained by encapsulating semiconductor chips in a relatively thick resin, and then grinding the upper surface of the encapsulating resin to decrease the thickness of the encapsulating resin to a predetermined value.

That is, according to the present invention, as a semiconductor chip resin encapsulation method for attaining the above principal object, there is provided a semiconductor chip resin encapsulation method, including a resin filling and curing step of encapsulating a plurality of semiconductor chips, which have been bonded onto a substrate, in a molten resin, and curing the molten resin, and
comprising a grinding step of grinding an upper surface of the cured resin to decrease the thickness of the encapsulating resin to a predetermined value.

Preferably, in the resin filling and curing step, the semiconductor chips on the substrate are covered with a box-shaped mold having an open lower surface, and the resin is filled into the space within the mold. In the resin filling and curing step, it is preferred that the resin is filled to a position 100 μm or more, particularly, 200 μm or more, upwardly of the uppermost site of the semiconductor chip.

### BRIEF DESCRIPTION OF THE DRAWINGS

FIG. 1 is a perspective view showing a substrate onto which semiconductor chips are to be bonded.

FIG. 2 is a perspective view showing a state in which a plurality of semiconductor chips are bonded onto the substrate in a wire bonding mode.

FIG. 3 is an enlarged sectional view showing the state in which the semiconductor chip is bonded onto the substrate in the wire bonding mode.

FIG. 4 is an enlarged sectional view showing a state in which the semiconductor chips are bonded in two stages onto the substrate in the wire bonding mode.

FIG. 5 is an enlarged sectional view showing a state in which the semiconductor chip is bonded onto the substrate in a flip chip bonding mode.

FIG. 6 is a perspective view showing a state in which the semiconductor chips bonded onto the substrate are covered with molds.

FIG. 7 is a sectional view showing the state in which the semiconductor chips bonded onto the substrate are covered with the mold.

FIG. 8 is a perspective view showing a state in which the semiconductor chips bonded onto the substrate are resin-encapsulated.

FIG. 9 is an enlarged sectional view showing the state in which the semiconductor chip bonded onto the substrate is resin-encapsulated.

FIG. 10 is a perspective view showing a state in which the semiconductor chips bonded onto the substrate and resin-encapsulated are secured onto a support plate.

FIG. 11 is a schematic sectional view showing a mode of grinding the upper surface of the resin encapsulating the semiconductor chips bonded onto the substrate.

FIG. 12 is an enlarged sectional view showing a state after the thickness of the resin is decreased to a predetermined value by grinding the upper surface of the resin encapsulating the semiconductor chip bonded onto the substrate.

### DETAILED DESCRIPTION OF THE PREFERRED EMBODIMENTS

Preferred embodiments of the semiconductor chip resin encapsulation method according to the present invention will now be described in further detail by reference to the accompanying drawings.

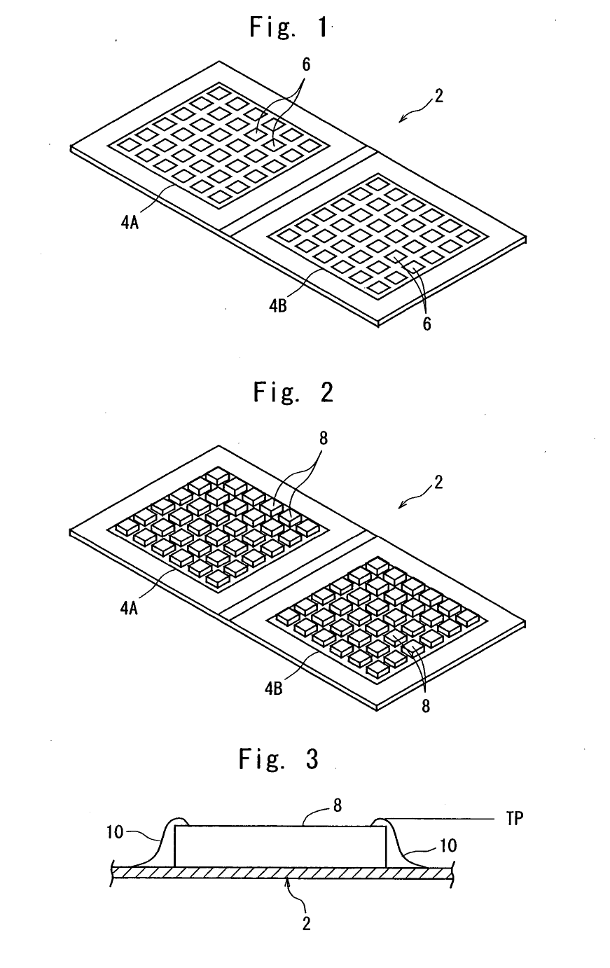

FIG. 1 shows a substrate 2. The illustrated substrate 2 is in the form of a rectangular plate as a whole, and two rectangular regions 4A and 4B are defined on the face of the substrate. A plurality of (36 in the illustrated embodiment) mounting regions 6 are arrayed in a matrix in each of the two rectangular regions 4A and 4B arranged in parallel. Required electrodes and wiring (not shown) are disposed in each of the mounting regions 6 which are rectangular.

With further reference to FIG. 2 along with FIG. 1, a semiconductor chip 8 is bonded to each of the mounting regions 6 disposed on the substrate 2. In further detail, the semiconductor chip 8 is secured onto each of the mounting regions 6 by a suitable securing means (not shown) such as an adhesive. Electrodes of the semiconductor chip 8 and electrodes of the mounting region 6 are connected together. In a mode called wire bonding, a wire 10 is disposed between the electrodes to connect the electrodes, as clearly shown in FIG. 3.

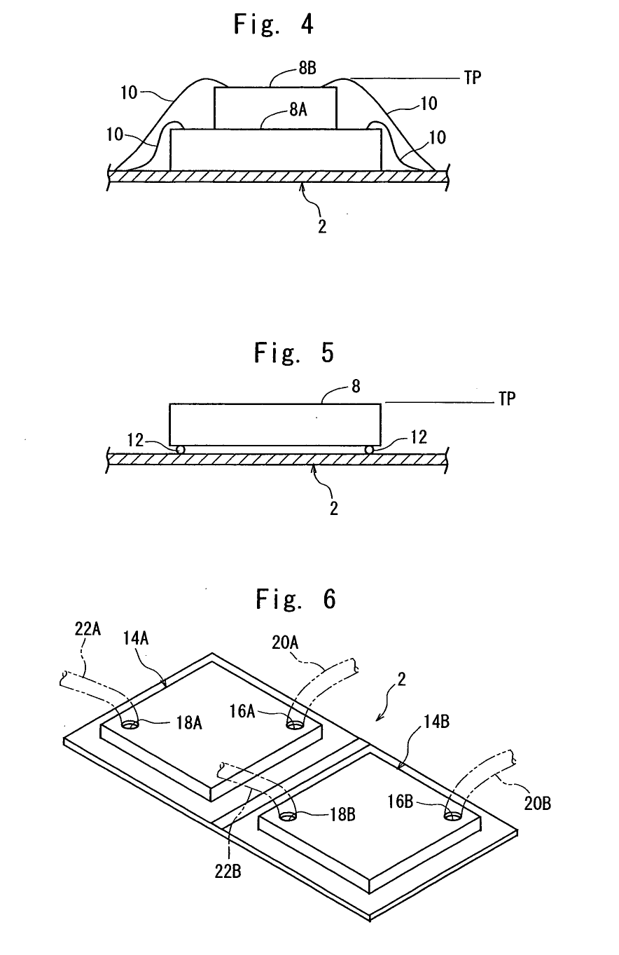

FIG. 4 shows an embodiment in which semiconductor chips 8A and 8B are secured in two stages to the mounting region 6, and electrodes of the semiconductor chips 8A and 8B are connected to electrodes of the mounting region 6 by wires 10. The connection between the electrodes of the semiconductor chip 8 (or 8A and 8B) and the electrodes of the mounting region 6 can also be performed in a mode called wireless bonding using no wire. FIG. 5 shows an embodiment in which electrodes of the semiconductor chip 8 and electrodes of the mounting region 6 are connected together in a flip chip bonding mode, a typical example of wireless bonding. In the mode illustrated in FIG. 5, the electrodes of the semiconductor chip 8 and the electrodes of the mounting region 6 are connected together by bumps 12.

In the semiconductor chip resin encapsulation method of the present invention, a resin filling and curing step is carried out first of all. In the resin filling and curing step, which will be explained with reference to FIG. 6 along with FIG. 2, the semiconductor chips 8 are covered with molds 14A and 14B. In the illustrated embodiment, the plurality of (36) semiconductor chips 8 bonded to the mounting regions 6 of the rectangular region 4A are covered with one common mold 14A, while the plurality of (36) semiconductor chips 8 bonded to the mounting regions 6 of the rectangular region 4B are covered with one common mold 14B. Each of the molds 14A and 14B is in the shape of a box having an open lower surface. Thus, a resin filling space is defined between the mold 14A and the semiconductor chips 8 bonded to the rectangular region 4A of the substrate 2 and its mounting regions 6. Similarly, a resin filling space is defined between the mold 14B and the semiconductor chips 8 bonded to the rectangular region 4B of the substrate 2 and its mounting regions 6. In the illustrated embodiment, resin inlets 16A and 16B and resin outlets 18A and 18B are formed in top walls of the molds 14A and 14B, respectively. Resin incoming pipes 20A and 20B are connected to the resin inlets 16A and 16B, respectively, and resin outgoing pipes 22A and 22B are connected to the resin outlets 18A and 18B, respectively.

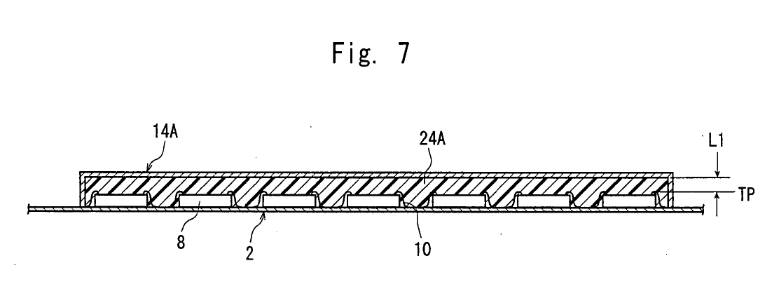

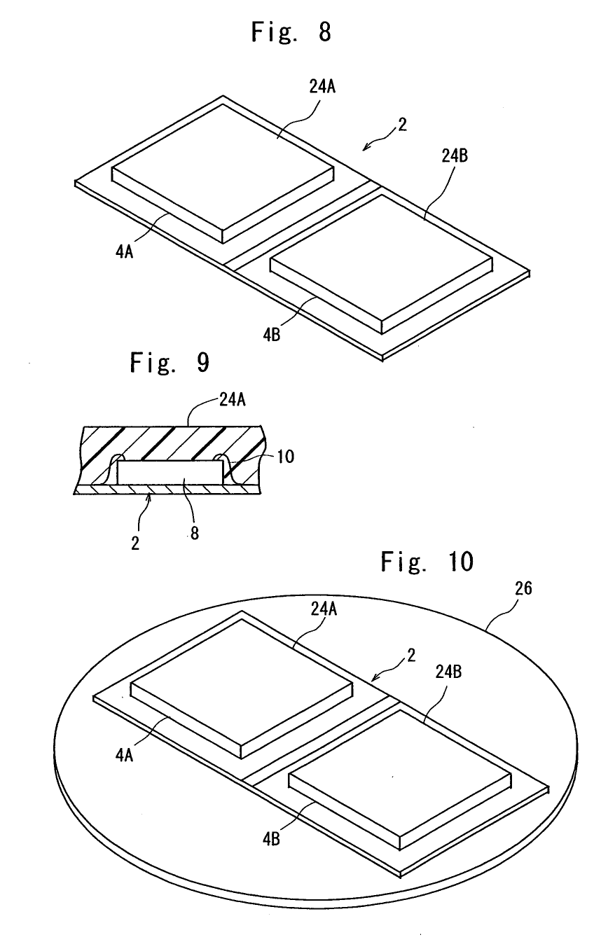

Then, molten resins 24A and 24B (FIGS. 7 and 8) are filled into the above-mentioned spaces through the resin incoming pipes 20A and 20B and the resin inlets 16A and 16B. Filling of the resins is carried out until the above spaces are filled with the molten resins substantially completely. Part of the molten resins is flowed out of the spaces through the resin outlets 18A and 18B and the resin outgoing pipes 22A and 22B. The resins may be phenolic resins or epoxy resins incorporating a filler such as silica particles.

As clearly shown in FIG. 7, it is important that a sufficient clearance to permit a required flow of the resin be present between the uppermost site TP of the semiconductor chips 8 and the inner surface of the top wall of each of the molds 14A and 14B, with the semiconductor chips 8 being covered with the molds 14A and 14B. The dimension L1 between the uppermost site of the semiconductor chips 8 and the inner surface of the top wall of each of the molds 14A and 14B is preferably 100 μm or more, particularly 200 μm or more. The term “uppermost site”, as used herein, refers to the uppermost site TP of the wire 10 in the embodiment shown in FIG. 3, refers to the uppermost site TP of the wire 10 relevant to the semiconductor chip 8B at the upper stage in the embodiment shown in FIG. 4, and refers to the top position TP of the semiconductor chip itself in the embodiment shown in FIG. 5.

Upon curing of the resins 24A and 24B filled into the aforementioned spaces defined within the molds 14A and 14B, the molds 14A and 14B are removed. FIGS. 8 and 9 show a state after removal of the molds 14A and 14B. On the substrate 2, there are the resin 24A encapsulating the semiconductor chips 8 bonded to the rectangular region 4A, and the resin 24B encapsulating the semiconductor chips 8 bonded to the rectangular region 4B.

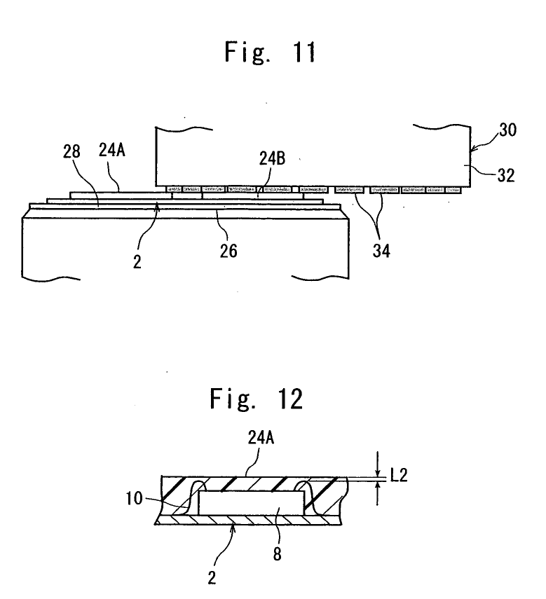

In the semiconductor chip resin encapsulation method of the present invention, it is important that after the resins 24A and 24B are cured and the molds 14A and 14B are removed, the upper surfaces of the resins 24A and 24B are ground to decrease the thicknesses of the resins 24A and 24B to sufficiently small predetermined values. Such grinding can be performed advantageously by a grinding machine which is marketed by Disco Corporation under the trade name “DAG120”. In performing the grinding, the substrate 2 is fixed, for example via wax, on a circular support plate 26 formed from a suitable thin metal plate of aluminum or the like, as shown in FIG. 10. Then, as shown in FIG. 11, the support plate 26 is placed on a chuck plate 28 of the grinding machine, and the atmosphere is sucked through the chuck plate 28 formed from a porous material to attract the support plate 26 onto the chuck plate 28. The grinding machine is equipped with a grinding wheel 30, and the grinding wheel 30 is caused to act on the upper surfaces of the resins 24A and 24B to grind the upper surfaces of the resins 24A and 24B. In more detail, the grinding wheel 30 is constructed of an annular support member 32, and many grinding pieces 34 fixed to the lower end of this support member 32. Each of the grinding pieces 34 is formed by bonding diamond grains together by a suitable binder. In grinding the upper surfaces of the resins 24A and 24B by the grinding wheel 30, the chuck plate 28 is rotated about its central axis extending substantially vertically, and the grinding wheel 30 is rotated about its central axis extending substantially vertically. In this state, the grinding pieces 34 of the grinding wheel 30 are pressed against the upper surfaces of the resins 24A and 24B, and the grinding wheel 30 and the chuck plate 28 are horizontally moved relative to each other. As shown in FIG. 12, after grinding of the resins 24A and 24B, it is preferred that the dimension L2 between the uppermost site of the semiconductor chip 8 and the upper surface of the resin 24A or 24B is of the order of 50 to 100 μm, especially 70 to 80 μm.

After the upper surfaces of the resins 24A and 24B are ground to decrease the thicknesses of the resins 24A and 24B to a predetermined value, the support plate 26 is removed from the chuck plate 28, and heated to melt the wax, thereby separating the substrate 2 from the support plate 26. Then, the resins 24A and 24B encapsulating the semiconductor chips 8 are divided, together with the substrate 2, at the sites between the adjacent semiconductor chips 8 to form individual CSP's. The division of the substrate 2 and the resins 24A and 24B can be performed advantageously, for example, by cutting with a rotating blade (not shown), irradiation with a laser beam, or application of a liquid jet.

While the preferred embodiments of the semiconductor chip resin encapsulation method constructed according to the present invention have been described by reference to the accompanying drawings, it is to be understood that the present invention are not limited to such embodiments, but various changes and modifications may be made without departing from the scope of the present invention.

What we claim is:

1. A semiconductor chip resin encapsulation method, including a resin filling and curing step of encapsulating a plurality of semiconductor chips, which have been bonded onto a substrate, in a molten resin, and curing the molten resin, and
comprising a grinding step of grinding an upper surface of the cured resin to decrease a thickness of the encapsulating resin to a predetermined value.

2. The semiconductor chip resin encapsulation method according to claim 1, wherein in the resin filling and curing step, the semiconductor chips on the substrate are covered with a box-shaped mold having an open lower surface, and the resin is filled into a space within the mold.

3. The semiconductor chip resin encapsulation method according to claim 1 or 2, wherein in the resin filling and curing step, the resin is filled to a position 100 μm or more upwardly of an uppermost site of the semiconductor chips.

4. The semiconductor chip resin encapsulation method according to claim 3, wherein in the resin filling and curing step, the resin is filled to a position 200 μm or more upwardly of the uppermost site of the semiconductor chips.
